(19) United States
(12) Patent Application Publication
(10) Pub. No.: US 2007/0108869 A1
(43) Pub. Date: May 17, 2007

(54) Driving and control apparatus of piezoelectric ultrasonic motor

(75) Inventors: Burhanettin Koc, Sungnam (KR); Jung Ho Ryu, Suwon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/593,595

(22) Filed: Nov. 7, 2006

(30) Foreign Application Priority Data
Nov. 7, 2005 (KR) 10-2005-0106147

(51) Int. Cl. H01L 41/107

(52) U.S. Cl. 310/316.01

(57) ABSTRACT

In a driving and control apparatus of a piezoelectric ultrasonic motor, a controller controls a selection of a first channel or a second channel of the piezoelectric ultrasonic motor as a driving channel. A switch part selects one of the first and second channels as the driving channel and the other as a detection channel, and supplies the driving voltage to the piezoelectric ultrasonic motor through the selected driving channel. A phase detector detects a voltage outputted from the piezoelectric ultrasonic motor through the detection channel, calculates a phase deviation, and outputs a phase difference voltage corresponding to the phase deviation. A voltage controlled oscillator generates the oscillation voltage and controls a phase of the oscillation voltage according to the phase difference voltage. A frequency divider divides the oscillation voltage by two to generate the driving voltage, and supplies the divided oscillation voltage to the piezoelectric ultrasonic motor through the driving channel.

### RELATED APPLICATION

The present application is based on, and claims priority from, Korean Application Number 2005-106147, filed Nov. 07, 2005, the disclosure of which is hereby incorporated by reference herein in its entirety.

### BACKGROUND OF THE INVENTION

1. Field of the Invention

The present invention relates to a driving and control apparatus of a piezoelectric ultrasonic motor, and more particularly, to a driving and control apparatus of a piezoelectric ultrasonic apparatus, which supplies the driving voltage through one of the two electrodes of the piezoelectric ultrasonic motor generating the elliptical vibration, detects the voltage through the other electrode, and making the phase difference between the driving voltage and the detection voltage be zero in a phase locked loop (PLL) scheme, thereby achieving the operation more efficiently.

2. Description of the Related Art

Generally, a piezoelectric device generates a strain or voltage when an electric field or a stress is applied thereto. A piezoelectric stator using the piezoelectric device is driven at a resonance frequency ranging from several tens of kHz to several hundreds of kHz and can provide a rotor with a strain amplified by a stack or strain expansion structure. Such a piezoelectric stator may use itself as a vibrator, or may be used in combination with a structure with a specific shape.

A piezoelectric ultrasonic motor using the piezoelectric device is called a traveling wave, surface wave, or surfing type motor. The piezoelectric ultrasonic motor is driven by a principle of superposing two driving waves with a predetermined phase difference.

FIG. 1 is a block diagram illustrating a conventional driving and control apparatus of a piezoelectric ultrasonic motor.

Referring to FIG. 1, the conventional driving and control apparatus includes a frequency/phase controller 10, a high-speed inverter 20, a pulse encoder 40, a current-voltage phase difference detector 50, and a microcontroller 60. The frequency/phase controller 10 receives frequency and phase information to generate square waves with respect to two phases. The high-speed inverter 20 converts the square waves into AC voltages with respect to the two phases and provides the AC voltages to an ultrasonic motor 30. The pulse encoder 40 accesses and encodes information about the frequency and phase applied to the ultrasonic motor 30. The current-voltage phase difference detector 50 detects a phase difference between a voltage VA and a current IA applied to the ultrasonic motor 30 and outputs the detected phase difference in a form of an impedance phase angle. The microcontroller 60 receives the impedance phase angle from the current-voltage phase difference detector 50 to output the frequency and phase information for making the ultrasonic motor 30 follow the resonance frequency of the ultrasonic motor 30.

The driving and control apparatus of the piezoelectric ultrasonic motor is disclosed in Korean Laid-Open Patent Publication No. 2002-0055465.

However, the conventional driving and control apparatus has to generate two driving waves in order to drive the piezoelectric ultrasonic motor, and also requires a current detector and/or a voltage detector in order to detect the current and the voltage. Thus, the conventional driving and control apparatus has a problem in that its structure is complicated and its manufacturing cost increases.

### SUMMARY OF THE INVENTION

Accordingly, the present invention is directed to a driving and control apparatus of a piezoelectric ultrasonic motor that substantially obviates one or more problems due to limitations and disadvantages of the related art.

An object of the present invention is to provide a driving and control apparatus of the piezoelectric ultrasonic motor, which supplies the driving voltage through one of the two electrodes of the piezoelectric ultrasonic motor generating the elliptical vibration, detects the voltage through the other electrode, and making the phase difference between the driving voltage and the detection voltage be zero in a phase locked loop (PLL) scheme, thereby achieving the operation more efficiently.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a driving and control apparatus of a piezoelectric ultrasonic motor, which has a first electrode and a second electrode and generates an elliptical vibration according to a driving voltage applied through the first and second electrodes. The driving and control apparatus includes: a controller for controlling a selection of the first channel or the second channel as a driving channel, the first channel and the second channel being connected to the first electrode and the second electrode, respectively; a switch part for selecting one of the first and second channels as the driving channel and the other as a detection channel according to the channel selection control of the controller, and supplying the driving voltage to the piezoelectric ultrasonic motor through the selected driving channel; a phase detector for detecting a voltage outputted from the piezoelectric ultrasonic motor through the detection channel, calculating a phase deviation representing that a phase difference between an oscillation voltage having two times the frequency of the driving voltage and the detection voltage is out of 90°, and outputting a phase difference voltage corresponding to the phase deviation; a voltage controlled oscillator for generating the oscillation voltage and controlling a phase of the oscillation voltage according to the phase difference voltage outputted from the phase detector; and a frequency divider for dividing the oscillation voltage from the voltage controlled oscillator by two to generate the driving voltage, and supplying the divided oscillation voltage to the piezoelectric ultrasonic motor through the driving channel.

The driving and control apparatus may further include a low pass filter for removing power noise and AC component contained in the phase difference voltage outputted from the phase detector.

The switch part may include: a first switch for connecting an output terminal of the voltage controlled oscillator to the first channel connected to the first electrode of the piezoelectric ultrasonic motor according to the channel selection control of the controller; and a second switch for connecting the output terminal of the voltage controlled oscillator to the second channel connected to the second electrode of the piezoelectric ultrasonic motor.

The phase detector may include: a first AND gate for ANDing the driving voltage and the detection voltage; a second AND gate for ANDing an output signal of the first AND gate and the oscillation voltage to detect a phase difference between the driving voltage and the detection voltage; and a phase difference voltage generating unit for calculating the phase deviation, in which the phase difference is out of 90° by the second AND gate, and outputting the phase difference voltage corresponding to the phase deviation.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a block diagram illustrating a conventional driving and control apparatus of a piezoelectric ultrasonic motor;

FIG. 2 is a block diagram illustrating a driving and control apparatus of a piezoelectric ultrasonic motor according to an embodiment of the present invention;

FIGS. 3A and 3B are block diagrams illustrating switching operations of the driving and control apparatus of FIG. 2;

FIGS. 4A to 4D are diagrams of the piezoelectric ultrasonic motor of FIG. 2;

FIGS. 5A and 5B are diagrams illustrating an elliptical vibration of the piezoelectric ultrasonic motor of FIG. 2;

FIG. 6 is a graph illustrating a vibration mode of the piezoelectric ultrasonic motor of FIG. 2;

FIG. 7 is a diagram of a phase detector of FIG. 2;

FIGS. 8A and 8B are timing diagrams illustrating an operation of the phase detector of FIG. 7; and

FIGS. 9(a) and 9(b) are graphs illustrating a gain and a phase difference of the piezoelectric ultrasonic motor of FIG. 2, respectively.

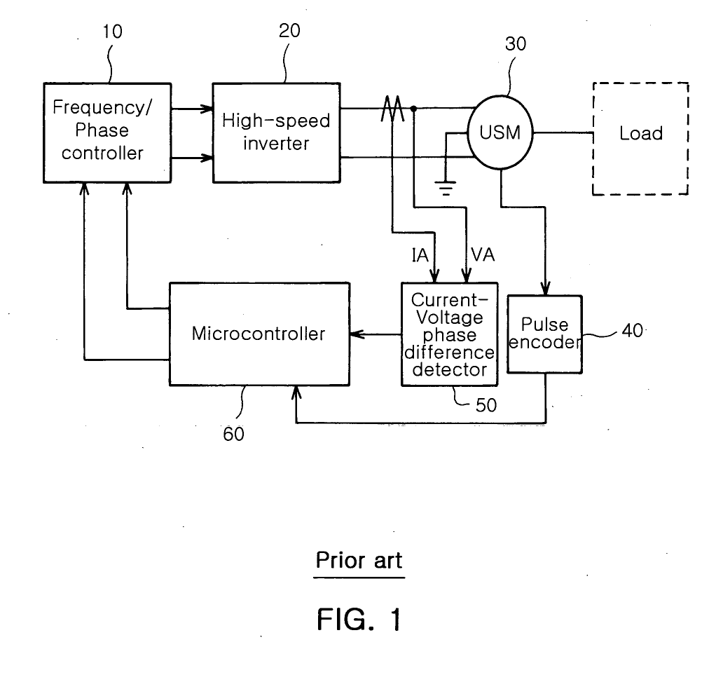

### DETAILED DESCRIPTION OF THE INVENTION

Reference will now be made in detail to the preferred embodiments of the present invention, examples of which are illustrated in the accompanying drawings. The same reference numerals are used to refer to the same elements throughout the drawings.

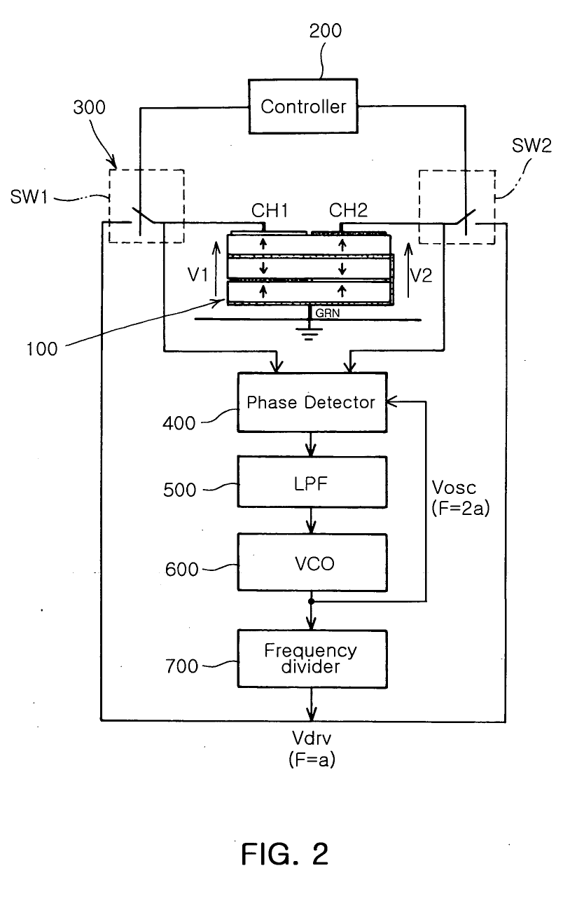

FIG. 2 is a block diagram illustrating a driving and control apparatus of a piezoelectric ultrasonic motor according to an embodiment of the present invention.

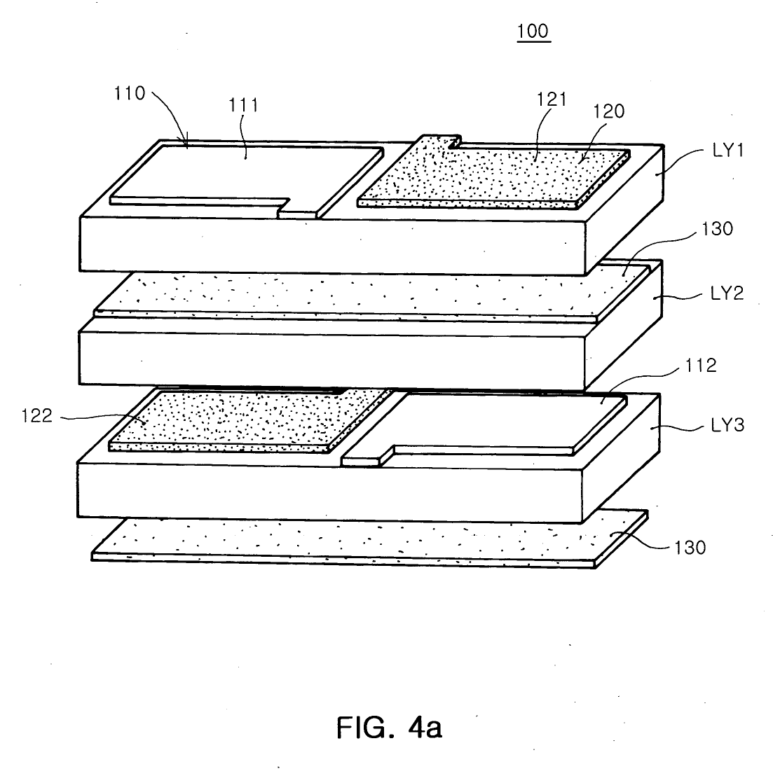

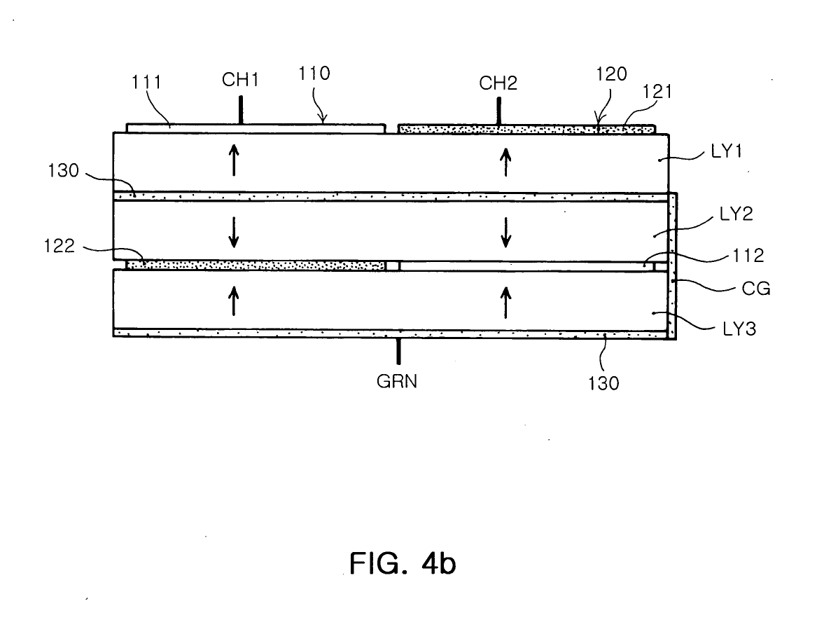

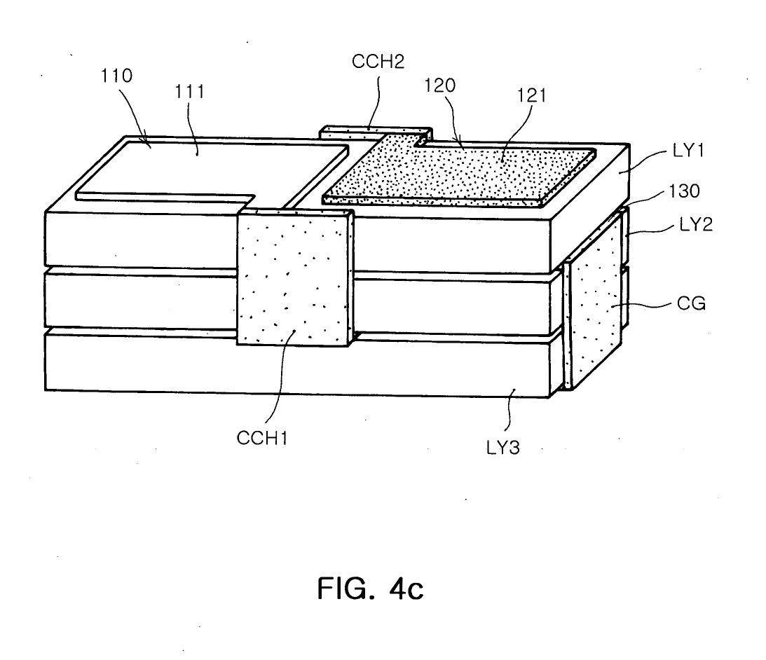

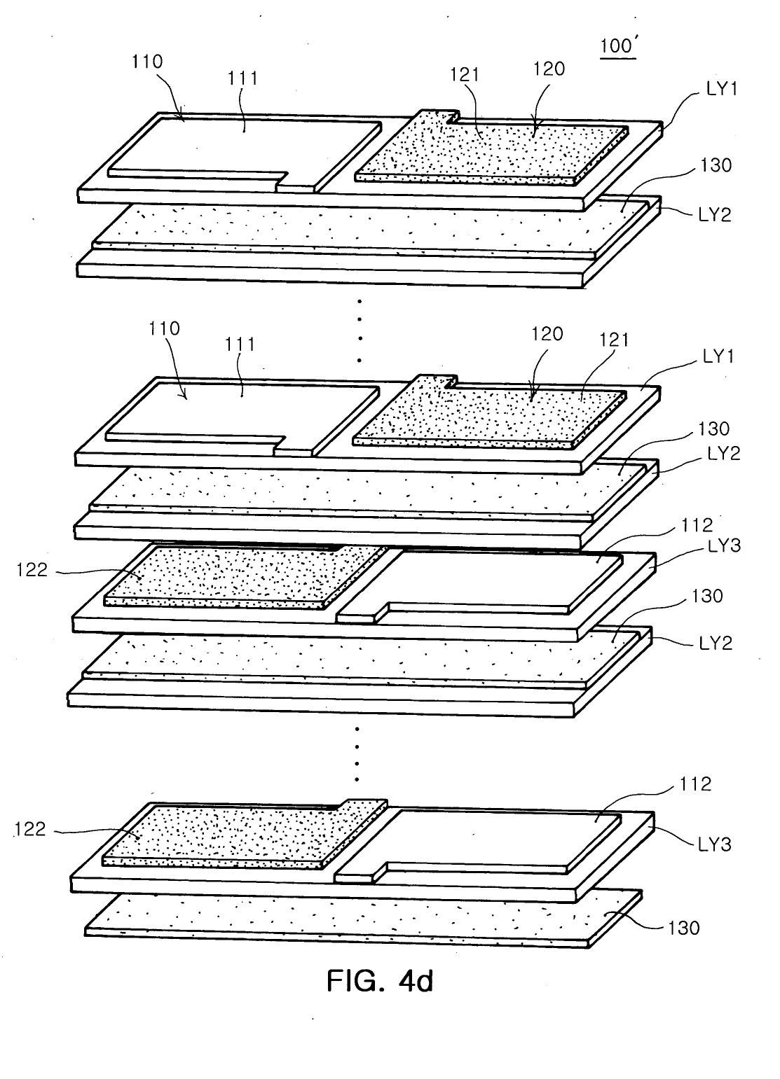

Referring to FIG. 2, the driving and control apparatus according to an embodiment of the present invention drives a piezoelectric ultrasonic motor 100 that has a first electrode 110 (shown in FIG. 4a) and a second electrode 120(shown in FIG. 4a) and generates an elliptical vibration by overlapping a length-direction vibration and a curve-direction vibration according to a driving voltage (Vdrv) applied to the first electrode 110 and the second electrode 120. The driving and control apparatus includes a controller 200, a switch part 300, a phase director 400, a voltage controlled oscillator (VCO) 600, and a frequency divider 700.

A first channel CH1 and a second channel CH2 are connected to the first electrode 110 and the second electrode 120 of the piezoelectric ultrasonic motor 100, respectively. The controller 200 controls the switch part 300 to select one of the first and second channels CH1 and CH2 as a driving channel.

The switch part 300 selects one of the first and second channels CH1 and CH2 as the driving channel and the other as a detection channel according to the channel selection control of the controller 200. The driving voltage (Vdrv) is supplied to the piezoelectric ultrasonic motor 100 through the selected driving channel.

The phase detector 400 detects a voltage supplied from the piezoelectric ultrasonic motor 100 through the detection channel. Then, the phase detector 400 calculates a phase deviation (Δφ) representing that a phase difference (dφ) between an oscillation voltage (Vosc) having two times the frequency of the driving voltage and the detection voltage (Vdet) is out of 90°, and outputs a phase difference voltage corresponding to the phase deviation (Δφ).

The VCO 600 generates the oscillation voltage (Vosc) and controls the phase of the oscillation voltage (Vosc) according to the phase difference voltage outputted from the phase detector 400.

The frequency divider 700 divides the oscillation voltage (Vosc, F=2a) from the VCO 600 by two to generate the driving voltage (Vdrv, F=a). The driving voltage (Vdrv) is supplied to the piezoelectric ultrasonic motor 100 through the driving channel selected by the switch part 300.

In order to supply a DC voltage in which power noise or AC component is removed, the driving and control apparatus may further include a low pass filter (LPF) 500 for removing the power noise or AC component contained in the phase difference voltage outputted from the phase detector 400.

In addition, the switch part 300 includes a first switch SW1 and a second switch SW2. According to the channel selection control of the controller 200, the first switch SW1 connects the output terminal of the VCO 600 to the first channel CH1, which is connected to the first electrode of the piezoelectric ultrasonic motor 100, and the second switch SW2 connects the output terminal of the VCO 600 to the second channel CH2, which is connected to the second electrode of the piezoelectric ultrasonic motor 100.

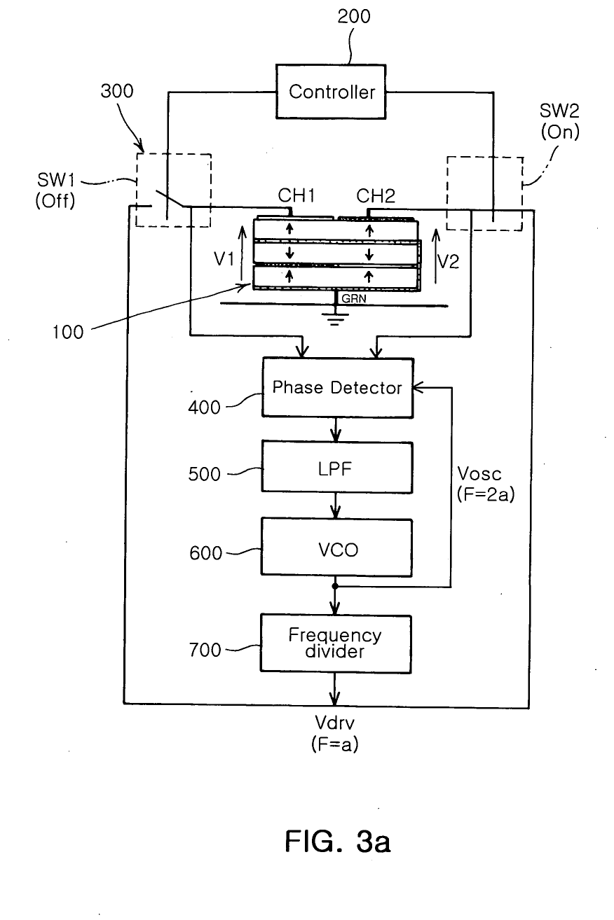

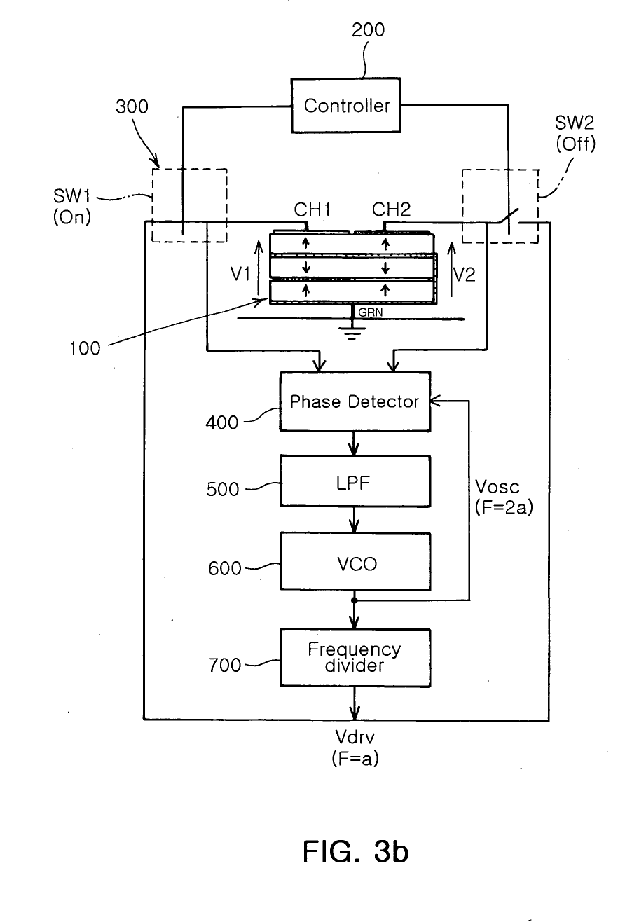

An operation of the driving and control apparatus according to the present invention will be described below in detail. First, the controller 200 selects one of the first channel CH1 and the second channel CH2, which are respectively connected to the first electrode 110 and the second electrode 120 of the piezoelectric ultrasonic motor 100, as the driving channel according to the user's selection. As illustrated in FIGS. 3A or 3B, the switch part 300 operates to select the first channel CH1 or the second channel CH2 according to the channel selection control of the controller 200. The other channel that is not selected as the driving channel serves as the detection channel.

FIGS. 3A and 3B are block diagrams illustrating the switching operations of the driving and control apparatus of FIG. 2. Referring to FIG. 3A, when the first switch SW1 is off and the second switch SW2 is on according to the channel selection control of the controller 200, the first channel CH1 is selected as the driving channel and the driving voltage (Vdrv) is supplied through the first channel CH1 to the first electrode 110 of the piezoelectric ultrasonic motor 100.

Referring to FIG. 3B, when the first switch SW1 is on and the second switch SW2 is off according to the channel selection control of the controller 200, the second channel CH2 is selected as the driving channel and the driving voltage (Vdrv) is supplied through the second channel CH2 to the second electrode 120 of the piezoelectric ultrasonic motor 100.

In this manner, when the driving voltage (Vdrv) is supplied to the piezoelectric ultrasonic motor 100, the piezoelectric ultrasonic motor 100 generates the elliptical vibration. The piezoelectric ultrasonic motor 100 will be described below in more detail with reference to FIGS. 4A to 4D.

FIGS. 4A to 4D are diagrams of the piezoelectric ultrasonic motor of FIG. 2.

Referring to FIGS. 4A to 4D, the piezoelectric ultrasonic motor 100 includes the first electrode 110 and the second electrode 120 and causes the length-direction vibration and the curve-direction vibration according to the driving signal applied through the electrodes 110, 111 and 112 and the electrodes 120, 121 and 122, thereby generating the elliptical vibration.

For example, as illustrated in FIG. 4A, the piezoelectric ultrasonic motor 100 includes a first ceramic sheet LY1, a middle ceramic sheet LY2, and a second ceramic sheet LY3. The first ceramic sheet LY1 has the first upper electrode 111 and the second upper electrode 121 separated from each other on its top surface. The middle ceramic sheet LY2 is disposed under the first ceramic sheet LY1 and has a ground electrode 130 on its top surface. The second ceramic sheet LY3 is disposed under the middle ceramic sheet LY2 and has the first lower electrode 112 and the second lower electrode 122 on its top surface and a ground electrode 130 on its bottom surface. The electrodes 110, 111 and 112 and the electrodes 120, 121 and 122 are extended up to the outside of the ceramic sheets LY1, LY2 and LY3 in a predetermined direction.

The ceramic sheets LY1, LY2 and LY3 are vertically stacked, as illustrated in FIG. 4B.

Polarization directions (arrow directions) of the ceramic sheets LY1, LY2 and LY3 are alternated in order to simultaneously vibrate the left side of the first ceramic sheet LY1 and the right side of the second ceramic sheet LY3, and the right side of the first ceramic sheet LY1 and the right side of the second ceramic sheet LY3.

FIG. 4C is a perspective view of the piezoelectric ultrasonic motor where external electrodes are formed in the stacked ceramic sheet structure. A first external electrode CCH1 is formed on a first side of the stacked ceramic sheet structure to connect the first upper electrode 111 to the second lower electrode 112, and a second external electrode CCH2 is formed on a second side of the stacked ceramic sheet structure to connect the second upper electrode 121 to the second lower electrode 122. In addition, a third external electrode CG is formed on a third side of the stacked ceramic sheet structure to connect the ground electrodes 130, which are formed on the top surface of the middle ceramic sheet LY2 and the bottom surface of the second ceramic sheet LY3.

Since the driving signal is simultaneously applied through the external electrodes CCH1, CCH2 and CG to the electrodes disposed diagonally, the ceramic sheets disposed diagonally can be vibrated. This vibration is transferred to the outside through a driving tip 140 formed one side of the stacked ceramic sheet structure.

FIG. 4D illustrates a modification of the piezoelectric ultrasonic motors 100 of FIGS. 4A to 4C.

In the piezoelectric ultrasonic motor 100′ of FIG. 4D, first ceramic sheets LY1 and middle ceramic sheets LY2 are alternately stacked to form an upper vibration region. Here, each of the first ceramic sheets LY1 has a first upper electrode 111 and a second upper electrode 121 separated from each other on its top surface, and each of the middle ceramic sheets LY2 is disposed under each of the first ceramic sheets and has a ground electrode 130 on its top surface.

In addition, second ceramic sheets LY3 and middle ceramic sheets LY2 are alternately stacked under the above-described stacked structure to form a lower vibration region. Here, each of the second ceramic sheets LY3 has a first lower electrode 112 and a second lower electrode 122 on its top surface, and each of the middle ceramic sheet LY2 is disposed under each of the second ceramic sheets LY3 and has a ground voltage 130 on its top surface. Meanwhile, a ground electrode 130 is formed on the bottom surface of the second ceramic sheet disposed at the lowermost position.

Polarization directions of the stacked ceramic sheets LY1, LY2 and LY3 are alternated as illustrated in FIG. 4B. Also, the first electrode 110, the external electrodes CCH1,CCH2 AND CG1 for connecting the second electrode 120, and the ground electrodes 130 are formed as illustrated in FIG. 4C.

Through the external electrodes, the portions located at the diagonal positions of the upper vibration region and the lower vibration region can be simultaneously vibrated.

In order to generate the vibration in the portions located at the diagonal positions, it is preferable that the number of the ceramic sheets stacked to form the upper vibration region is identical to the number of the ceramic sheets stacked to form the lower vibration region, but the present invention is not limited thereto.

Meanwhile, electrode protection sheets (not shown) covering the electrodes may be further stacked in order to protect the electrodes formed on the stacked ceramic sheets of FIG. 4D.

In FIG. 4, the piezoelectric ultrasonic motor 100′ has the vibration regions located in the diagonal lines among the four vibration regions, that is, the up/down/right/left vibration regions in the vertically stacked ceramic sheets.

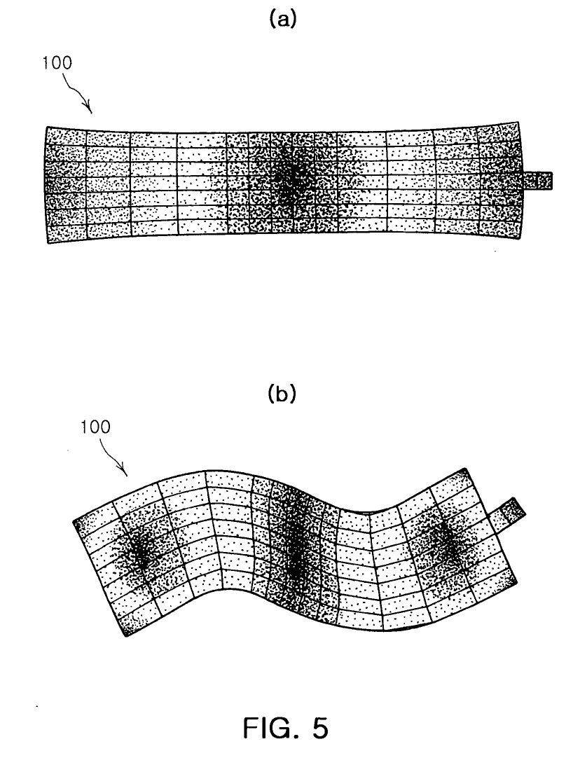

However, the piezoelectric ultrasonic motor 100′ used in the driving and control apparatus according to the present invention simultaneously generates the length-direction vibration of FIG. 5(a) and the curve-direction vibration of FIG. 5(b) by the driving signals applied through the first and second electrodes. Therefore, the present invention can be applied to any piezoelectric ultrasonic motors if they generate the elliptical vibration. The piezoelectric ultrasonic motor can have various shapes and structures.

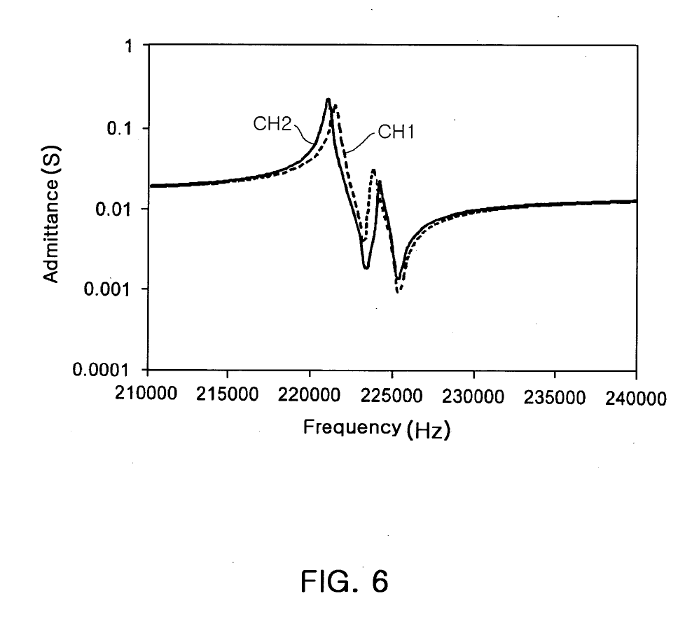

The vibrations at the first and second channels when the piezoelectric ultrasonic motor generates the elliptical vibration are illustrated in FIG. 6.

FIG. 6 is a graph illustrating a vibration mode of the piezoelectric ultrasonic motor of FIG. 2.

It can be seen from FIG. 6 that an admittance is highest when a “CH1” graph and a “CH2” graph have a phase difference of 90°. The admittance is an index representing how well the signal flows. That is, it can be seen that the vibration efficiency is high when the piezoelectric ultrasonic motor has the phase difference of 90°.

Referring again to FIG. 2, the phase detector 400 detects the voltage outputted from the piezoelectric ultrasonic motor 100 through the detection channel, calculates the phase deviation (Δφ) representing that a phase difference (dφ) between an oscillation voltage (Vosc) having two times the frequency of the driving voltage and the detection voltage (Vdet) is out of 90°, and outputs a phase difference voltage corresponding to the phase deviation (Δφ).

The VCO 600 generates the oscillation voltage (Vosc) having the preset frequency (F=2a) and controls the phase of the driving voltage (Vdrv) according to the phase difference voltage outputted from the phase detector 400.

The frequency divider 700 divides the oscillation voltage (Vosc) outputted from the VCO 600 by two to generate the driving voltage (Vdrv). The driving voltage (Vdrv) is supplied to the piezoelectric ultrasonic motor 100 through the driving channel selected by the switch part 300.

The driving and control apparatus including the LPF 500 can remove the power noise or AC component contained in the phase difference voltage, thereby providing the clearer phase difference voltage.

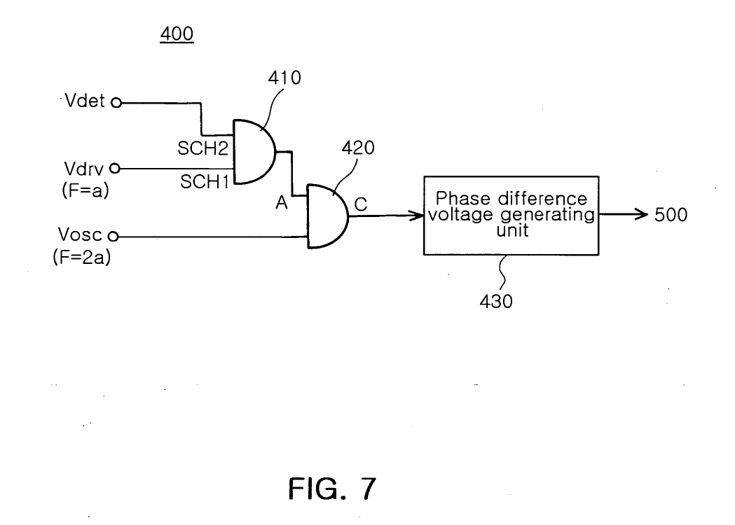

FIG. 7 is a diagram of the phase detector of FIG. 2.

Referring to FIG. 7, the phase detector 400 includes a first AND gate 410 for ANDing the driving voltage (Vdrv, F=2a) and the detection voltage (Vdet), a second AND gate 420 for ANDing an output signal of the first AND gate 410 and the oscillation voltage (Vosc, F=2a) to detect the phase difference (Δφ) between the driving voltage (Vdrv) and the detection voltage (Vdet), and a phase difference voltage generating unit 430 for calculating the phase deviation (Δφ) in which the phase difference (dφ) is out of 90° by the second AND gate 420 and outputting the phase difference voltage corresponding to the phase deviation (Δφ).

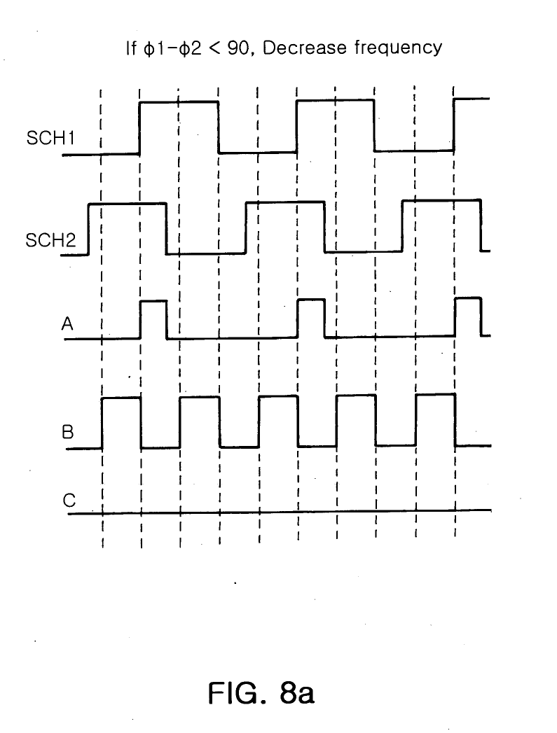

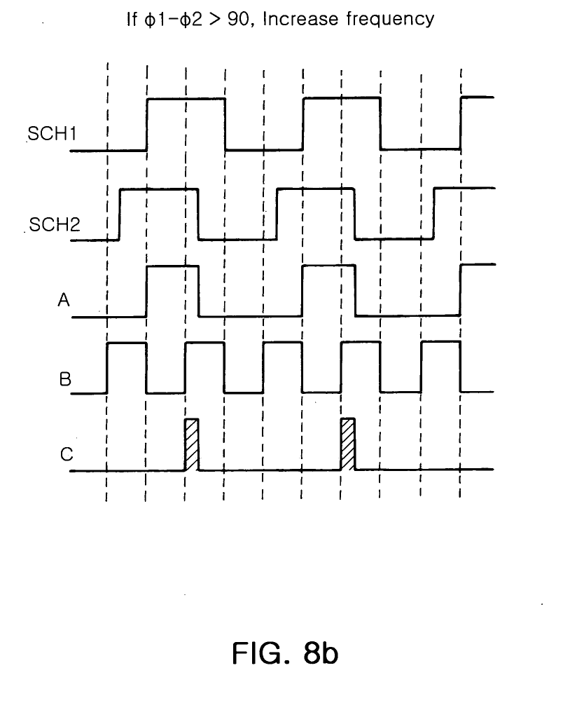

FIGS. 8A and 8B are timing diagrams illustrating an operation of the phase detector of FIG. 7. An operation of the phase detector will be described below reference to FIGS. 7 and 8.

Referring to FIGS. 7 and 8A, when the first channel CH1 is selected as the driving channel, the first AND gate 410 performs the logic AND operation on the driving voltage (Vdrv) and the detection voltage (Vdet). The second AND gate 420 performs the logic AND operation on the output signal A of the first AND gate 410 and the oscillation voltage (Vosc) to detect the phase difference (dφ) between the driving voltage (Vdrv) and the detection voltage (Vdet), and outputs the detected phase difference (dφ) C to the phase difference voltage generating unit 430. The phase difference voltage generating unit 430 calculates the phase deviation (Δφ) and outputs the phase difference voltage to the LPF 500.

When the phase difference (dφ=dφ1−dφ2) is less than 90°, that is, when the phase deviation (Δφ=dφ−90°) is negative, the phase difference signal (dφ) C outputted from the second AND gate 420 has no pulse, as illustrated in FIG. 8A. Therefore, the phase difference voltage generating unit 430 recognizes that there is no phase deviation. In this case, the VCO 600 has to decrease the frequency.

On the other hand, when the phase difference (dφ=dφ1−dφ2) is greater than 90°, that is, when the phase deviation (Δφ=dφ−90°) is positive, the phase difference signal (dφ) C outputted from the second AND gate 420 has a predetermined pulse, as illustrated in FIG. 8B. Then, the generation of the phase deviation is notified to the phase difference voltage generating unit 430. At this point, the phase difference voltage generating unit 430 generates the phase difference voltage according to the predetermined pulse. In this case, the VCO 600 has to increase the frequency.

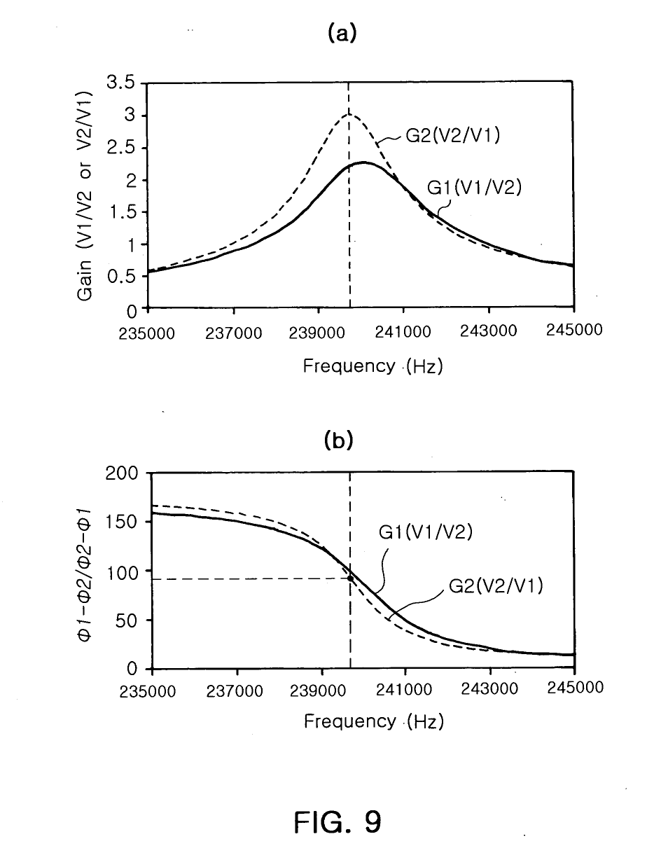

FIGS. 9(a) and 9(b) are graphs illustrating a gain and a phase difference of the piezoelectric ultrasonic motor of FIG. 2, respectively.

Specifically, FIG. 9(a) is a graph illustrating the gain of the piezoelectric ultrasonic motor. When the second channel CH2 is selected as the driving channel, the gain (V1/V2) of the piezoelectric ultrasonic motor 100 is given by the “G1” graph. The gain (V1/V2) of the piezoelectric ultrasonic motor 100 means the ratio of the output voltage (V1) to the input voltage (V2).

When the first channel CH1 is selected as the driving channel, the gain (V2/V1) of the piezoelectric ultrasonic motor 100 is given by the “G2” graph. The gain (V2/V1) of the piezoelectric ultrasonic motor 100 means the ratio of the output voltage (V2) to the input voltage (V1).

FIG. 9(b) is a graph illustrating the phase difference of the piezoelectric ultrasonic motor. When the second channel CH2 is selected as the driving channel, the phase difference (φ1−φ2) between the input voltage (V2) and the output voltage (V1) is almost 90°. When the first channel CH1 is selected as the driving channel, the phase difference (φ2−φ1) between the input voltage (V1) and the output voltage (V2) is almost 90°.

As described above, the driving and control apparatus of the piezoelectric ultrasonic motor supplies the driving voltage through one of the two electrodes of the piezoelectric ultrasonic motor generating the elliptical vibration, detects the voltage through the other electrode, and making the phase difference between the driving voltage and the detection voltage be zero in a phase locked loop (PLL) scheme, thereby achieving the operation more efficiently. Since the driving and control apparatus is implemented more simply, its manufacturing cost can be reduced.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A driving and control apparatus of a piezoelectric ultrasonic motor, the piezoelectric ultrasonic motor having a first electrode and a second electrode and generating an elliptical vibration according to a driving voltage applied through the first and second electrodes, the driving and control apparatus comprising:
a controller for controlling a selection of the first channel or the second channel as a driving channel, the first channel and the second channel being connected to the first electrode and the second electrode, respectively;
a switch part for selecting one of the first and second channels as the driving channel and the other as a detection channel according to the channel selection control of the controller, and supplying the driving voltage to the piezoelectric ultrasonic motor through the selected driving channel;
a phase detector for detecting a voltage outputted from the piezoelectric ultrasonic motor through the detection channel, calculating a phase deviation representing that a phase difference between an oscillation voltage having two times the frequency of the driving voltage and the detection voltage is out of 90°, and outputting a phase difference voltage corresponding to the phase deviation;
a voltage controlled oscillator for generating the oscillation voltage and controlling a phase of the oscillation voltage according to the phase difference voltage outputted from the phase detector; and
a frequency divider for dividing the oscillation voltage from the voltage controlled oscillator by two to generate the driving voltage, and supplying the divided oscillation voltage to the piezoelectric ultrasonic motor through the driving channel.

2. The driving and control apparatus of claim 1, further comprising a low pass filter for removing power noise and AC component contained in the phase difference voltage outputted from the phase detector.

3. The driving and control apparatus of claim 1, wherein the switch part comprises:
a first switch for connecting an output terminal of the voltage controlled oscillator to the first channel connected to the first electrode of the piezoelectric ultrasonic motor according to the channel selection control of the controller; and
a second switch for connecting the output terminal of the voltage controlled oscillator to the second channel connected to the second electrode of the piezoelectric ultrasonic motor.

4. The driving and control apparatus of claim 1, wherein the phase detector comprises:
a first AND gate for ANDing the driving voltage and the detection voltage;
a second AND gate for ANDing an output signal of the first AND gate and the oscillation voltage to detect a phase difference between the driving voltage and the detection voltage; and
a phase difference voltage generating unit for calculating the phase deviation, in which the phase difference is out of 90° by the second AND gate, and outputting the phase difference voltage corresponding to the phase deviation.
